(19) United States
(12) Patent Application Publication
(10) Pub. No.: US 2020/0042223 A1
(43) Pub. Date: Feb. 6, 2020

(54) SYSTEM AND METHOD FOR FACILITATING A HIGH-DENSITY STORAGE DEVICE WITH IMPROVED PERFORMANCE AND ENDURANCE

(71) Applicant: Alibaba Group Holding Limited, George Town (KY)

(72) Inventor: Shu Li, Bothell, WA (US)

(73) Assignee: Alibaba Group Holding Limited, George Town (KY)

(21) Appl. No.: 16/277,686

(22) Filed: Feb. 15, 2019

Related U.S. Application Data
(60) Provisional application No. 62/713,911, filed on Aug. 2, 2018.

(51) Int. Cl. G06F 3/06; G06F 12/0802; G06F 11/10; G11C 29/52; H03M 13/29

(52) U.S. Cl. CPC G06F 3/0644; G06F 3/0619; G06F 3/0647; G06F 3/064; G06F 3/0656; G06F 2212/2022; G06F 12/0802; G06F 11/1068; G11C 29/52; H03M 13/2906; G06F 2212/1032; G06F 3/0679

(57) ABSTRACT

Embodiments described herein provide a system comprising a storage device. The storage device includes a plurality of non-volatile memory cells, each of which is configured to store a plurality of data bits. During operation, the system forms a first region in the storage circuitry comprising a subset of the plurality of non-volatile memory cells in such a way that a respective cell of the first region is reconfigured to store fewer data bits than the plurality of data bits. The system also forms a second region comprising a remainder of the plurality of non-volatile memory cells. The system can write host data received via a host interface in the first region. The write operations received from the host interface are restricted to the first region. The system can also transfer valid data from the first region to the second region.

### RELATED APPLICATION

This application claims the benefit of U.S. Provisional Application No. 62/713,911, Attorney Docket No. ALI-A14229USP, titled “Method and System of High-Density 3D QLC NAND Flash Enablement with the Improved Performance and Endurance,” by inventor Shu Li, filed 2 Aug. 2018, the disclosure of which is incorporated herein by reference in its entirety.

### BACKGROUND

### Field

This disclosure is generally related to the field of storage management. More specifically, this disclosure is related to a system and method for facilitating a high-density storage device (e.g., based on quad-level cells (QLCs)) that can provide high endurance and improved performance.

### Related Art

A variety of applications running on physical and virtual devices have brought with them an increasing demand for computing resources. As a result, equipment vendors race to build larger and faster computing equipment (e.g., processors, storage, memory devices, etc.) with versatile capabilities. However, the capability of a piece of computing equipment cannot grow infinitely. It is limited by physical space, power consumption, and design complexity, to name a few factors. Furthermore, computing devices with higher capability are usually more complex and expensive. More importantly, because an overly large and complex system often does not provide economy of scale, simply increasing the size and capability of a computing device to accommodate higher computing demand may prove economically unviable.

With the increasing demand for computing, the demand for high-capacity storage devices is also increasing. Such a storage device typically needs a storage technology that can provide large storage capacity as well as efficient storage/retrieval of data. One such storage technology can be based on Not AND (NAND) flash memory devices (or flash devices). NAND flash devices can provide high capacity storage at a low cost. As a result, NAND flash devices have become the primary competitor of traditional hard disk drives (HDDs) as a persistent storage solution. To increase the capacity of a NAND flash device, more bits are represented by a single NAND flash cell in the device. For example, a triple-level cell (TLC) and a quad-level cell (QLC) can represent 3 and 4 bits, respectively. Consequently, a QLC NAND flash device maintains 2⁴=16 threshold voltage levels to denote its 4 bits.

As the density of a cell increases, the data stored on the cell can become more vulnerable to leakage and noise, rendering long-term data retention in high-density NAND flash devices challenging. Maintaining the data quality and reliability of high-density NAND devices has become a significant benchmark for NAND flash device technology. As a result, a NAND flash device is typically designed in such a way that the programmed data on the device should meet a set of data retention requirements in a noisy environment for a threshold period of time.

Even though error-correction coding (ECC) has brought many desirable features of efficient data retention to NAND flash devices, many problems remain unsolved in efficient data retention and storage/retrieval of data.

### SUMMARY

Embodiments described herein provide a system comprising a storage device. The storage device includes a plurality of non-volatile memory cells, each of which is configured to store a plurality of data bits. During operation, the system forms a first region in the storage circuitry comprising a subset of the plurality of non-volatile memory cells in such a way that a respective cell of the first region is reconfigured to store fewer data bits than the plurality of data bits. The system also forms a second region comprising a remainder of the plurality of non-volatile memory cells. The system can write host data received via a host interface in the first region. The write operations received from the host interface are restricted to the first region. The system can also transfer valid data from the first region to the second region.

In a variation on this embodiment, the system can initiate the transfer in response to one of: (i) determining that a number of available blocks in the first region is below a threshold, and (ii) determining a proactive recycling.

In a variation on this embodiment, the system can rank a respective block in the first region to indicate a likelihood of transfer, select one or more blocks with a highest ranking, and determine data in valid pages of the one or more blocks as the valid data.

In a variation on this embodiment, the system can transfer the valid data to a buffer in a controller of the system and determine whether a size of the data in the buffer has reached a size of a block of the second region. If the size of the data in the buffer reaches the size of the block of the second region, the system writes the data in the buffer to a next available data block in the second region.

In a variation on this embodiment, the first and second regions can be accessible based on a first and a second non-volatile memory namespaces, respectively.

In a variation on this embodiment, the system can apply a first error-correction code (ECC) encoding to the host data for writing in the first region and apply a second ECC encoding to the valid data for transferring to the second region. The second ECC encoding is stronger than the first ECC encoding.

In a further variation, the system can apply a first ECC decoding corresponding to the first ECC encoding for transferring the valid data to the second region and apply a second ECC decoding corresponding to the second ECC encoding for reading data from the second region.

In a variation on this embodiment, the system writes the host data in the first region by determining a location indicated by a write pointer of the first region and programming the host data at the location of the first region. The location can indicate where data is to be appended in the first region.

In a further variation, if the host data is new data, the system generates a mapping between a virtual address of the host data to a physical address of the location of the first region. On the other hand, if the host data is an update to existing data, the system updates an existing mapping of the virtual address of the host data with the physical address of the location of the first region.

In a variation on this embodiment, a respective cell of the first region is a single-level cell (SLC) and a respective cell of the second region is a quad-level cell (QLC).

### BRIEF DESCRIPTION OF THE FIGURES

FIG. 1A illustrates an exemplary infrastructure based on high-density storage nodes with improved endurance and performance, in accordance with an embodiment of the present application.

FIG. 1B illustrates an exemplary voltage distribution of a high-density NAND cell with reduced noise margin.

FIG. 2 illustrates an exemplary architecture of a high-density storage node with multi-level storage cells, in accordance with an embodiment of the present application.

FIG. 3A illustrates exemplary namespaces of multi-level storage cells in a high-density storage node, in accordance with an embodiment of the present application.

FIG. 3B illustrates an exemplary data-flow path in a high-density storage node with multi-level storage cells, in accordance with an embodiment of the present application.

FIG. 4 illustrates an exemplary data transfer among storage regions of a high-density storage node, in accordance with an embodiment of the present application.

FIG. 5A presents a flowchart illustrating a method of a high-density storage device performing a write operation, in accordance with an embodiment of the present application.

FIG. 5B presents a flowchart illustrating a method of a high-density storage device performing a read operation, in accordance with an embodiment of the present application.

FIG. 5C presents a flowchart illustrating a method of a high-density storage device performing an inter-region data transfer, in accordance with an embodiment of the present application.

FIG. 6 illustrates an exemplary computer system that facilitates a high-density storage node with improved endurance and performance, in accordance with an embodiment of the present application.

FIG. 7 illustrates an exemplary apparatus that facilitates a high-density storage node with improved endurance and performance, in accordance with an embodiment of the present application.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the embodiments described herein are not limited to the embodiments shown, but are to be accorded the widest scope consistent with the principles and features disclosed herein.

### OVERVIEW

The embodiments described herein solve the problem of data retention and storage utilization in a high-density storage device by (i) operating a subset of the storage cells of the storage device at a low level and limiting user write operations to that subset; and (ii) executing an efficient data transfer technique from that subset to the rest of the storage cells that operate at a high level. The term “level” can refer to the number of bits a single data cell can store. For example, a single-level cell (SLC) can store one bit while a quad-level cell (QLC) can store four bits. These cells can be referred to as storage cells.

With existing technologies, the storage capacity of a high-density storage device can be increased using three-dimensional (3D) Not-AND (NAND). However, the production cost of 3D NAND can be significant and, hence, infeasible for mass-scale production. As a result, most high-density storage devices, such as solid-state devices (SSDs), are produced using planar (or two-dimensional (2D)) NAND. To facilitate high-capacity at a reduced cost, such high-density storage devices are built with QLCs. A QLC can represent 4 bits and, consequently, a QLC NAND maintains 2⁴=16 threshold voltage levels to denote its 4 bits. Therefore, the controller of the storage device needs to distinguish among 16 voltage levels to identify a corresponding bit pattern (e.g., 0101 versus 0100) stored in the QLC. In other words, the controller needs to uniquely identify 15 threshold voltage levels.

This high-density nature of data storage leads to a limited gap between adjacent voltage levels and corresponding tightly distributed threshold voltage levels. Over time, the distribution becomes “wider” and the threshold levels may overlap. Hence, the data stored (or programmed) in the cell can become noisy. The controller may not be able to detect the correct threshold voltage level and may read the stored data incorrectly. For example, due to noisy conditions, the controller may read “0101,” while the original data had been “0100.” In this way, the data retention capability of the storage cells in the flash device gradually weakens over the lifespan of the storage cells. The weakened data retention can limit the number of program-erase (PE) cycles for the storage device that, in turn, restricts drive write per day (DWPD) for the storage device. As a result, the long-term deployment of storage devices comprising high-level storage cells, such as QLCs, may become challenging.

To solve this problem, embodiments described herein provide a storage device that includes two regions: a low-level cell region (e.g., an SLC region) and a high-level cell region (e.g., a QLC region). It should be noted that low-level and high-level cell regions are relative to each other, and can include any cell level accordingly. The storage device can include a number of QLC NAND dies. A subset of the dies can be configured to form the SLC region. The storage cells in this region can be configured to operate as SLCs. The remainder of the QLC NAND dies can form the QLC region. In this way, the QLC-based storage device can be reconfigured into two different namespaces with corresponding isolated regions. These regions can be physically isolated or separated using the flash translation layer (FTL) of the storage device.

In some embodiments, the storage device can receive an instruction through an open channel command (e.g., using an open-channel SSD command), which instructs the controller to configure the storage cells of the SLC region to operate as SLCs instead of QLCs. In this way, a data page based on QLCs of the storage device can be configured to operate as a data page based on SLCs. When a storage cell is configured to operate as an SLC, the corresponding programming latency and read latency can be significantly shortened. In addition, since an SLC maintains only two threshold levels, the retention of an SLC is significantly higher than that of a QLC. Hence, the number of PE cycles an SLC can tolerate can be significantly higher; hence, when a QLC is configured as an SLC, the access latency and endurance can be significantly improved.

The storage device can have an SLC namespace and a QLC namespace, which allow access to the SLC and QLC regions, respectively. The namespaces can be SSD namespaces. Each namespace can include a set of logical blocks. The host device may determine that one SLC drive and one QLC drive are connected to the peripheral component interconnect express (PCIe) bus of the host device in parallel. The storage device can restrict the write operations issued by the host device to the SLC region. Therefore, the SLC drive can accommodate the write operations and the QLC drive can be “read-only” to the host device. The QLC drive only accommodates the write operations from the SLC drive in such a way that a large block of data from the SLC drive is sequentially written to the QLC drive (i.e., at the next available data block in the QLC drive). In this way, the SLC region of the storage device only accommodates the write operations from the host device, and the QLC region accommodates the read operations from the host device. The data flow can be unidirectional from the SLC region to the QLC region. However, the host device may read from both SLC and QLC regions.

In some embodiments, the garbage collection (GC) of the SLC region facilitates the data movement from the SLC region to the QLC region. During the garbage collection operation, the controller determines the valid pages of the SLC region, reads out the valid pages, and stores them in a garbage collection buffer (e.g., a dynamic random-access memory (DRAM)) in the controller. When the size of the data stored in the buffer reaches the size of a block (e.g., a read block of the storage device), the controller transfers (i.e., writes) the data to a corresponding QLC block. Both SLC and QLC regions accommodate sequential write operations and random read operations. However, the data is written into and erased from the QLC region on a block-by-block basis. Therefore, the QLC region may not need a garbage collection operation.

### Exemplary System

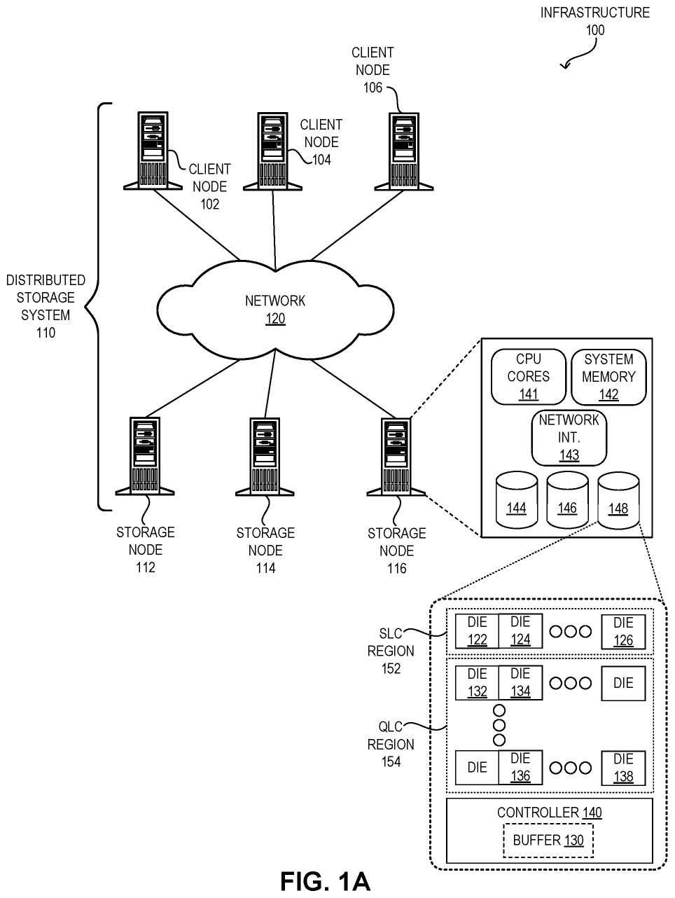

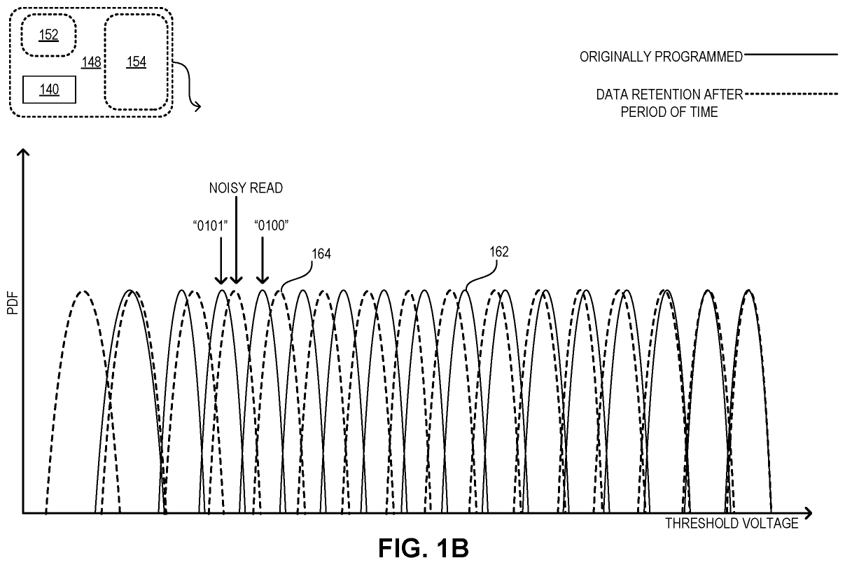

FIG. 1A illustrates an exemplary infrastructure based on high-density storage nodes with improved endurance and performance, in accordance with an embodiment of the present application. In this example, an infrastructure 100 can include a distributed storage system 110. System 110 can include a number of client nodes (or client-serving machines) 102, 104, and 106, and a number of storage nodes 112, 114, and 116. Client nodes 102, 104, and 106, and storage nodes 112, 114, and 116 can communicate with each other via a network 120 (e.g., a local or a wide area network, such as the Internet). A storage node can also include multiple storage devices. For example, storage node 116 can include components such as a number of central processing unit (CPU) cores 141, a system memory device 142 (e.g., a dual in-line memory module), a network interface card (NIC) 143, and a number of storage devices/disks 144, 146, and 148. Storage device 148 can be a high-density non-volatile memory device, such as a NAND-based SSD.

With existing technologies, to increase the storage capacity, storage device 148 can be composed of QLC NAND dies. Since each storage cell in storage device 148 can store 4 bits, controller 140 of storage device 148 needs to distinguish among 16 voltage levels to identify a corresponding bit pattern stored in the storage cell. In other words, controller 140 needs to uniquely identify 15 threshold voltage levels. However, the threshold voltage distribution can become noisy over time; hence, controller 140 may not be able to detect the correct threshold voltage level and may read the stored data incorrectly. In this way, the data retention capability of the storage cells in storage device 148 can gradually weaken over the lifespan of the storage cells. The weakened data retention can limit the number of PE cycles for storage device 148 that, in turn, restricts DWPD for storage device 148.

To solve this problem, storage device 148 can include two regions: a low-level cell region, such as SLC region 152, and a high-level cell region, such as QLC region 154. Storage device 148 can include a number of QLC NAND dies. A subset of the dies, such as QLC NAND dies 122, 124, and 126, form SLC region 152. The storage cells in SLC region 152 can be configured to operate as SLCs. The rest of the dies, such as QLC NAND dies 132, 134, 136, and 138, can form QLC region 154. In this way, even though storage device 148 can be a QLC-based storage device, storage device 148 can be reconfigured into two different namespaces with corresponding isolated regions 152 and 154. These regions can be physically isolated or separated using the FTL of storage device 148. In some embodiments, storage device 148 can receive an instruction through an open channel command (e.g., using an open-channel SSD command), which instructs controller 140 to configure the storage cells of SLC region 152 to operate as SLCs instead of QLCs.

In this way, a data page based on QLCs of storage device 148 can be configured to operate as a data page based on SLCs. When a storage cell is configured to operate as an SLC, the corresponding programming latency and read latency can be significantly shortened. Since an SLC maintains only two threshold levels, the retention of an SLC is significantly higher than that of a QLC. Hence, the number of PE cycles SLC region 152 can tolerate can be significantly higher than that of QLC region 154. The host write operations from storage node 116, which is the host device of storage device 148, can be random and frequent, and can lead to a large number of PE cycles on storage device 148.

To address the issue, controller 140 can limit the host write operations to SLC region 152, which is capable of maintaining data retention with high accuracy even with a large number of PE cycles. In addition, SLC region 152 allows the host write operations to execute with a lower latency compared to a QLC-based storage device. Controller 140 can operate QLC region 154 as a “read-only” device for storage node 116. QLC region 154 can only accommodate the write operations for the data stored in SLC region 152. In some embodiments, controller 140 can transfer data from SLC region 152 to QLC region 154 using the garbage collection operation of SLC region 152. During the garbage collection operation, controller 140 determines the valid pages of SLC region 152, reads out the valid pages, and stores them in a buffer 130 in controller 140.

When the size of the data stored in buffer 130 reaches the size of a block, controller 140 transfers the data to a corresponding QLC block in QLC region 154. Hence, the data flow can be unidirectional from SLC region 152 to QLC region 154. Since a single QLC can hold data stored in 4 SLCs and data is only written into QLC region 154 in a block-by-block basis, the write operations on QLC region 154 can have a lower frequency. This reduces the number of PE cycles on QLC region 154. In this way, the overall data retention and write latency is improved for storage device 148. It should be noted that, even though the storage capacity of storage device 148 can be reduced due to a fewer number of bits stored in SLC region 152, the significant increase in the number of PE cycles that storage device 148 can endure allows storage device 148 to be more feasible for deployment in system 110.

FIG. 1B illustrates an exemplary voltage distribution of a high-density NAND cell with reduced noise margin. The high-density nature of data storage in storage device 148 leads to a limited gap between adjacent voltage levels and corresponding tightly distributed threshold voltage levels. Over time, the distribution becomes “wider” and the threshold levels may overlap. For the QLCs in storage device 148, data retention over a period of time can cause the originally programmed threshold voltage distribution 162 (e.g., a probability density function (PDF)) to become distorted, thereby generating a distorted threshold voltage distribution 164.

Threshold voltage distribution 164 tends to shift from distribution 162 and becomes wider compared to distribution 162. Since the gap between adjacent levels is limited, threshold voltage distribution 164 can become significantly overlapping. Hence, the data stored (or programmed) in the QLCs can become noisy. Controller 140 may not be able to detect the correct threshold voltage level and may read the stored data incorrectly. For example, due to noisy conditions, controller 140 may read “0101,” while the original data had been “0100.” In this way, the data retention capability of the QLCs in storage device 148 may gradually weaken over the lifespan of the QLCs. The weakened data retention can limit the number of PE cycles for the QLCs.

However, by restricting the host write operations to SLC region 152, as described in conjunction with FIG. 1A, controller 140 reduces the number of PE cycles for QLC region 154. This increases the overall endurance of storage device 148. To further ensure safe data retention in both SLC region 152 and QLC region 154, controller 140 can detect the distortion of the threshold voltage distribution of a cell, consequently moving data from the cell by reading out and re-writing to another cell before any read error can happen. As a result, the long-term deployment of storage device 148 comprising high-level storage cells, such as QLCs, can become feasible.

### Exemplary Architecture and Data Flow

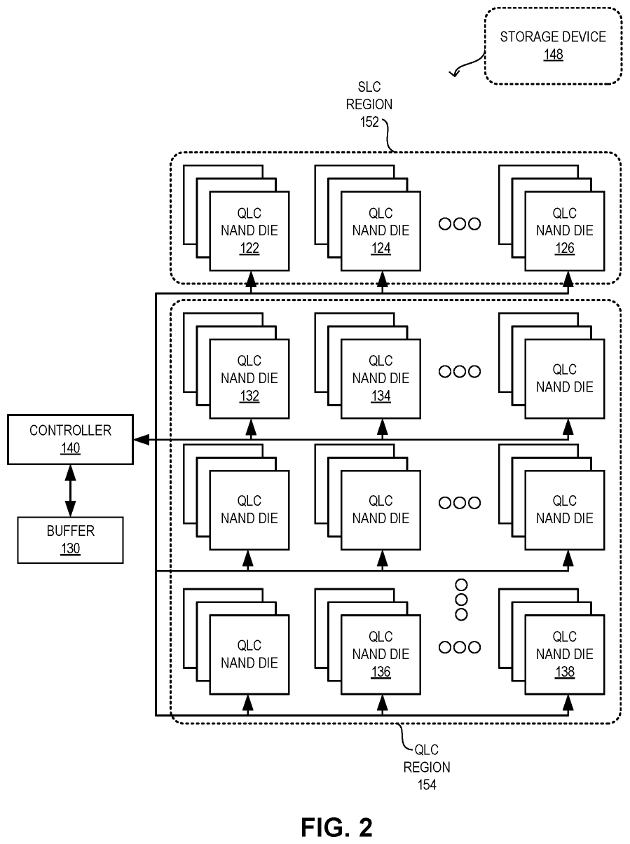

FIG. 2 illustrates an exemplary architecture of a high-density storage node with multi-level storage cells, in accordance with an embodiment of the present application. Even though storage device 148 can be a QLC drive (i.e., composed of QLC NAND dies), a subset of QLC NAND dies of storage device 148 can be reconfigured to generate two isolated regions—SLC region 152 and QLC region 154. The storage cells in the QLC NAND dies of SLC region 152 are configured as SLCs, and the storage cells in other QLC NAND dies are still used as QLCs. This facilitates a separate region, which is SLC region 152, within storage device 148 that can endure a high number of PE cycles with accurate data retention while providing low-latency storage operations (i.e., write operations).

In some embodiments, storage device 148 can receive an instruction through an open channel command (e.g., using an open-channel SSD command), which instructs controller 140 to configure the storage cells of SLC region 152 to operate as SLCs instead of QLCs. In this way, a data page based on QLCs of storage device 148 can be configured to operate as a data page based on SLCs. When a storage cell is configured to operate as an SLC, the corresponding programming latency can be significantly shortened. In addition, since an SLC maintains only two threshold levels, the retention of an SLC is significantly higher than that of a QLC. Hence, the number of PE cycles SLC region 152 can tolerate can be significantly higher than that of QLC region 154. In other words, by configuring the QLCs as SLCs, the latency and endurance of SLC region 152 can be significantly improved.

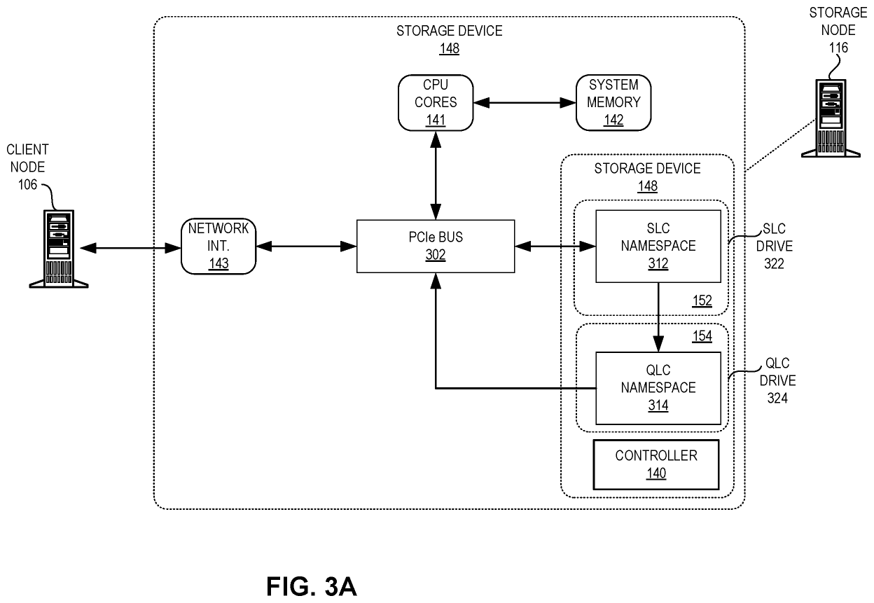

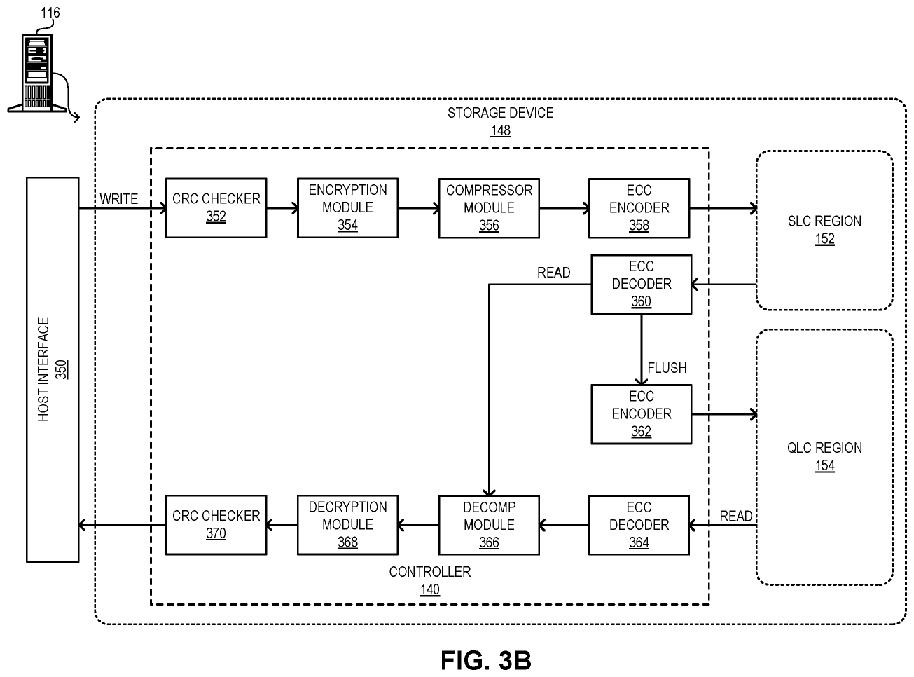

FIG. 3A illustrates exemplary namespaces of multi-level storage cells in a high-density storage node, in accordance with an embodiment of the present application. Storage device 148 can have an SLC namespace 312 and a QLC namespace 314, which allow access to the SLC and QLC regions 152 and 154, respectively. Namespaces 312 and 314 can be SSD namespaces. Each of namespaces 312 and 314 can include a set of logical blocks. Storage node 116, which is the host device of storage device 148, may determine SLC and QLC regions 152 and 154 as separate drives 322 and 324, respectively, coupled to PCIe bus 302 in parallel. Storage device 148 can restrict the write operations issued by storage node 116 to SLC region 152. To do so, upon receiving a write request from client node 106 via network interface card 143, controller 140 may only use SLC namespace 312 for the corresponding write operations.

In this way, SLC drive 322 can appear as a “read-write” drive and QLC drive 324 can appear as a “read-only” drive to storage node 116. Furthermore, QLC drive 324 can only accept the write operations for data stored in SLC drive 322 in such a way that a large block of data from SLC drive 322 is sequentially written to QLC drive 324 (i.e., at the next available data block in QLC drive 324). This restricts the write operations from storage node 116 in SLC region 152, but allows read operations from storage node 116 from SLC region 152 and QLC region 154. The data flow can be unidirectional from SLC region 152 to QLC region 154. However, storage node 116 may read from both SLC and QLC regions 152 and 154, respectively.

FIG. 3B illustrates an exemplary data-flow path in a high-density storage node with multi-level storage cells, in accordance with an embodiment of the present application. Since SLC region 152 can be separated from QLC region 154, the robustness of SLC region 152 against noise may not be affected by the operations on QLC region 154. An ECC encoding with high strength is usually associated with a long codeword length. Hence, the corresponding encoding and decoding operations increase the codec latency. To improve the latency, storage device 148 can maintain two different ECCs with different strengths for SLC region 152 and QLC region 154.

An ECC code with a moderate strength (e.g., the Bose-Chaudhuri-Hocquenghem (BCH) encoding) can be used for SLC region 152. On the other hand, an ECC code with high strength (e.g., the low-density parity-check (LDPC) encoding) can be used for QLC region 154 for efficient data retrieval from QLC region 154. Furthermore, since SLC and QLC regions 152 and 154 can be separated, the operations on these regions can be executed in parallel. In particular, the separation of read and write operations can provide improved performance for storage device 148.

Upon receiving a write instruction and corresponding host data via host interface 350 (e.g., a PCIe interface), controller 140 first performs a cyclic-redundancy check (CRC) using a CRC checker 352. This allows controller 140 to detect any error in the host data. Encryption module 354 then encrypts the host data based on an on-chip encryption mechanism, such as a self-encrypting mechanism for flash memory. Compressor module 356 then compresses the host data by encoding the host data using fewer bits than the received bits. Controller 140 encodes the host data with a moderate-strength ECC encoding using encoder 358 and writes the host data in SLC region 152.

QLC region 154 can only accept write operations for data stored in SLC region 152. Typically, data can be periodically flushed from SLC region 152 to QLC region 154 (e.g., using garbage collection). To flush data, controller 140 can first decode the data using decoder 360 that can decode data encoded with encoder 358. Controller 140 re-encodes the data with a high-strength ECC encoding using encoder 362. Controller 140 then stores the data in QLC region 154. It should be noted that, since a single QLC can hold the data stored in 4 SLCs, the number of write operations on QLC region 154 can be significantly reduced for storage device 148.

Storage node 116 (i.e., the host machine) can read data from both SLC region 152 and QLC region 154. To read data from SLC region 152, controller 140 can decode the data using decoder 360. On the other hand, since encoding for QLC region 154 is different, to read data from QLC region 154, controller 140 can decode the data using decoder 364 that can decode data encoded with encoder 362. Upon decoding the data, decompressor module 366 decompresses the data by regenerating the original bits. Decryption module 368 can then decrypt the on-chip encryption on the data. CRC checker 370 performs a CRC check on the decrypted user data to ensure the data is error-free. Controller 140 provides that user data to storage node 116 via host interface 340.

### Inter-Region Data Transfer

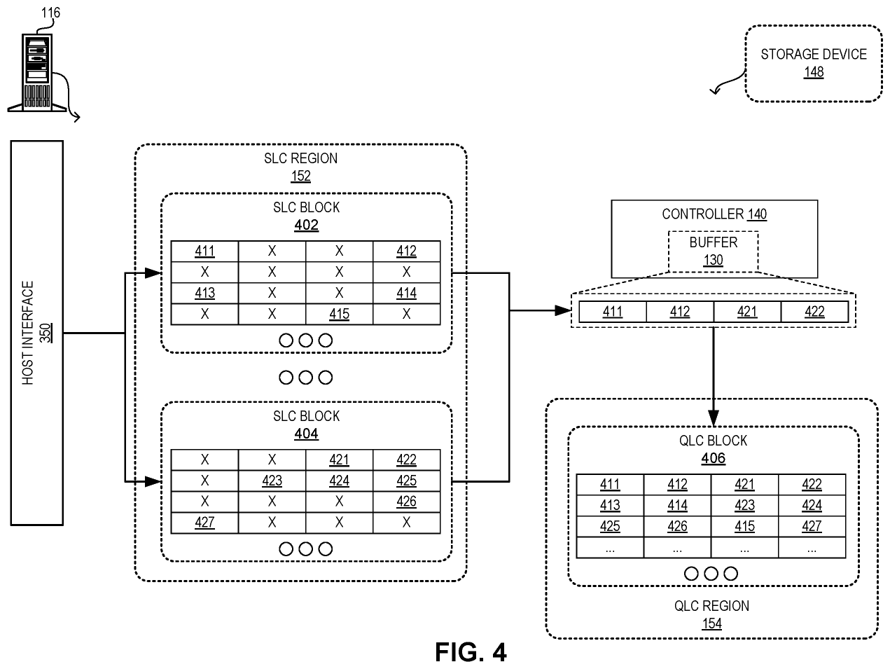

FIG. 4 illustrates an exemplary data transfer among storage regions of a high-density storage node, in accordance with an embodiment of the present application. SLC region 152 can include a number of blocks, which include blocks 402 and 404. A block can include a number of data units, such as data pages. The number of pages in the block can be configured for storage device 148. Controller 140 can restrict the write operations from host interface 350 to SLC region 152. Upon receiving a write instruction and corresponding host data, controller 140 appends the host data to the next available page in SLC region 152. If the host data is a new piece of data, controller 140 can map the physical address of the location to the virtual address of the host data (e.g., the virtual page address). On the other hand, if the host data updates an existing page, controller 140 marks the previous location as invalid (denoted with an “X”) and updates the mapping with the new location.

In some embodiments, the garbage collection of SLC region 152 facilitates the data movement from the SLC region to the QLC region. Controller 140 maintains a free block pool for SLC region 152. This free block pool indicates the number of free blocks in SLC region 152. When the number of free blocks in the free block pool falls to a threshold (e.g., does not include a sufficient number of free blocks over a predetermined number), controller 140 evaluates respective used blocks in SLC region 152 and ranks the blocks. The ranking can be based on time (e.g., the older the block, the higher the rank) and/or number of invalid pages (e.g., the higher the number of invalid pages, the higher the rank). It should be noted that, under certain circumstances (e.g., due to a user command), controller 140 can be forced to perform a proactive recycling. In that case, the garbage collection operation can be launched even though the number of free blocks is more than the threshold.

Controller 140 then selects the SLC blocks with the highest ranking for garbage collection. Suppose that controller 140 selects blocks 402 and 404. Block 402 can include valid pages 411, 412, 413, 414, and 415, and block 404 can include valid pages 421, 422, 423, 424, 425, 426, and 427. The rest of the pages of blocks 402 and 404 can be invalid. Controller 140 then determines the valid pages of blocks 402 and 404, reads out the valid pages, and stores them in buffer 130 in controller 140. For example, at some point in time, buffer 130 can include pages 411 and 412 of block 402, and pages 421 and 422 of block 404. When the size of the data stored in buffer 130 reaches the size of a block of QLC region 154, controller 140 transfers the data from buffer 130 to a QLC block 406 in QLC region 154. Since data is written into and erased from QLC region 154 on a block-by-block basis, a QLC block may not include an invalid page. Therefore, QLC region 154 may not need a garbage collection operation.

### Operations

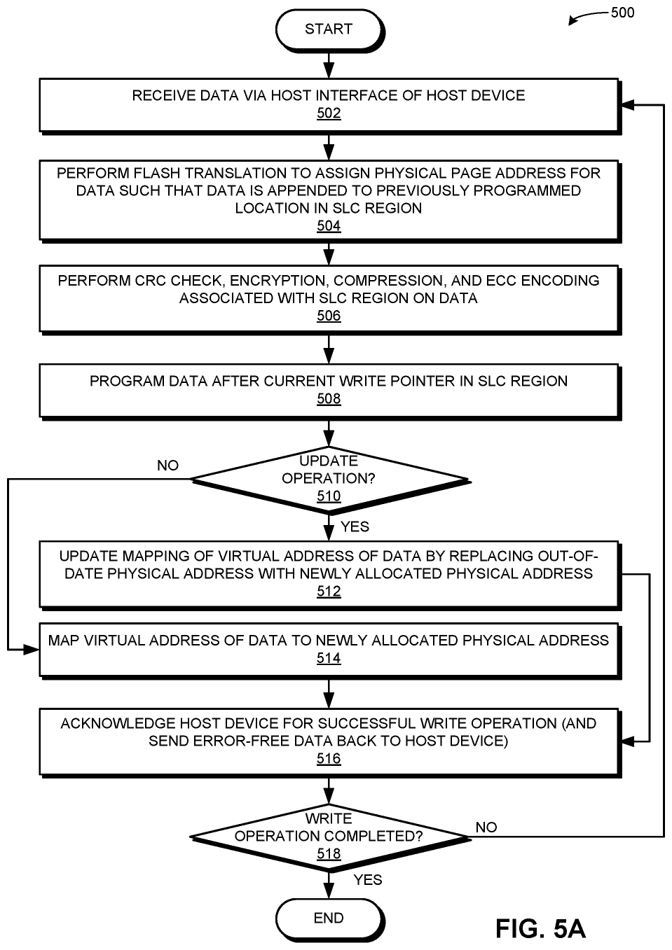

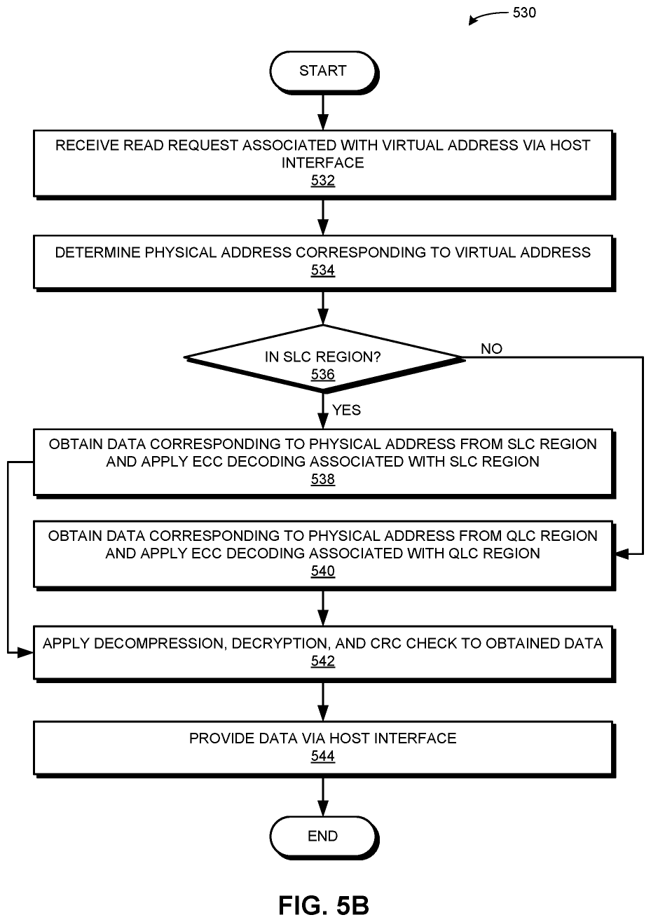

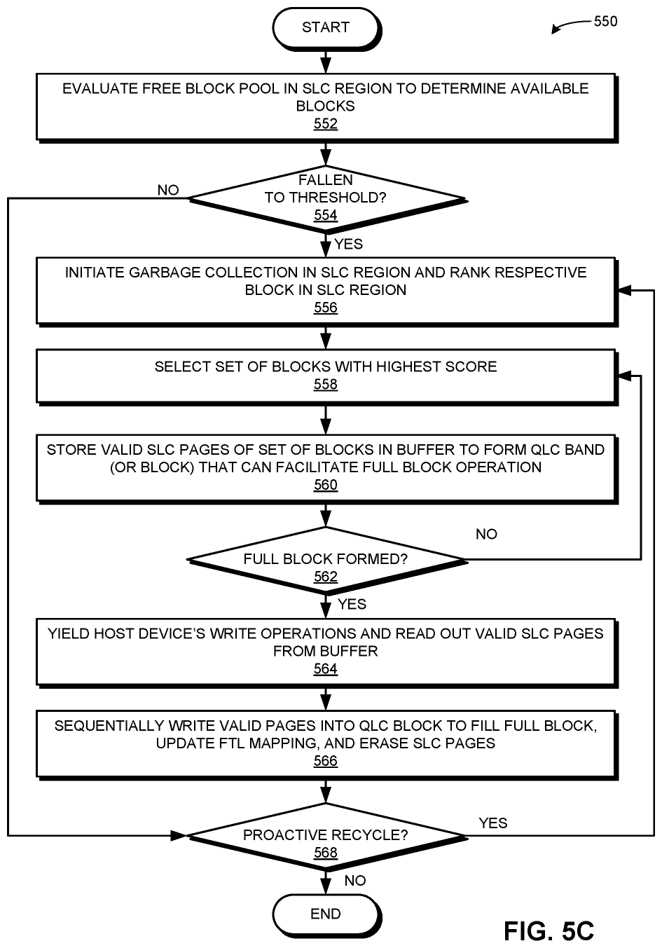

FIG. 5A presents a flowchart 500 illustrating a method of a high-density storage device performing a write operation, in accordance with an embodiment of the present application. During operation, the storage device can receive data via the host interface of the host device (operation 502). The storage device then performs the flash translation to assign a physical page address for the data such that the data is appended to a previously programmed location in the SLC region (operation 504). The storage device can perform CRC check, encryption, compression, and ECC encoding associated with the SLC region on the data (operation 506). The ECC encoding associated with the SLC region can be based on a medium-strength ECC code.

Subsequently, the storage node programs the data after the current write pointer in the SLC region (operation 508) and checks whether the write instruction is for an update operation (operation 510). The write pointer can indicate where data should be appended in the SLC region. The write pointer can then be moved forward based on the size of the data. If the write instruction is for an update operation, the storage node can update the mapping of the virtual address of the data by replacing the out-of-date physical address with the newly allocated physical address (operation 512).

If the write instruction is not for an update operation (i.e., for a new piece of data), the storage node can map the virtual address of the data to the newly allocated physical address (operation 514). Upon updating the mapping (operation 512) or generating the mapping (operation 514), the storage node acknowledges the host device for the successful write operation (operation 516). The storage node can also send the error-free data back to the host device. The storage node checks whether the write operation has been completed (operation 518). If not, the storage node can continue to receive data via the host interface of the host device (operation 502).

FIG. 5B presents a flowchart 530 illustrating a method of a high-density storage device performing a read operation, in accordance with an embodiment of the present application. During operation, the storage node receives a read request associated with a virtual address via the host interface (operation 532) and determines the physical address corresponding to the virtual address (operation 534) (e.g., based on the FTL mapping). The storage device then determines whether the physical address is in the SLC region (operation 536). If the physical address is in the SLC region (e.g., associated with the SLC namespace), the storage device obtains the data corresponding to the physical address from the SLC region and applies the ECC decoding associated with the SLC region (operation 538).

On the other hand, if the physical address is not in the SLC region (e.g., associated with the SLC namespace), the storage device obtains the data corresponding to the physical address from the QLC region and applies the ECC decoding associated with the QLC region (operation 540). Upon obtaining the data (operation 538 or 540), the storage device applies decompression, decryption, and CRC check to the obtained data (operation 542). The storage device then provides the data via the host interface (operation 544).

FIG. 5C presents a flowchart 550 illustrating a method of a high-density storage device performing an inter-region data transfer, in accordance with an embodiment of the present application. During operation, the storage device evaluates the free block pool in the SLC region to determine the available blocks (operation 552) and checks whether the number of available blocks has fallen to a threshold (operation 554). If the number of available blocks has fallen to a threshold, the storage device initiates the garbage collection in the SCL region and ranks a respective block in the SLC region (operation 556). The storage device then selects a set of blocks with the highest score (operation 558). The storage device then stores the valid pages of the set of blocks in a buffer to form a QLC band (or block) that can support a full block operation, such as a block-wise read operation (operation 560). The storage device then checks whether a full block has been formed (operation 562).

If a full block is not formed, the storage device continues to select a set of blocks with the highest score (operation 558). On the other hand, if a full block is formed, the storage device yields host device's write operation (e.g., relinquishes the control of the thread/process of the write operation and/or imposes a semaphore lock) and reads out the valid pages from the buffer (operation 564). The storage device then sequentially writes the valid pages into a QLC block, updates the FTL mapping, and erases the SLC pages (operation 566). Upon writing the valid pages into a QLC block (operation 566) or if the number of available blocks has not fallen to a threshold (operation 554), the storage device checks whether a proactive recycle has been invoked (operation 568). If invoked, the storage device initiates the garbage collection in the SCL region and ranks a respective block in the SLC region (operation 556).

### Exemplary Computer System and Apparatus

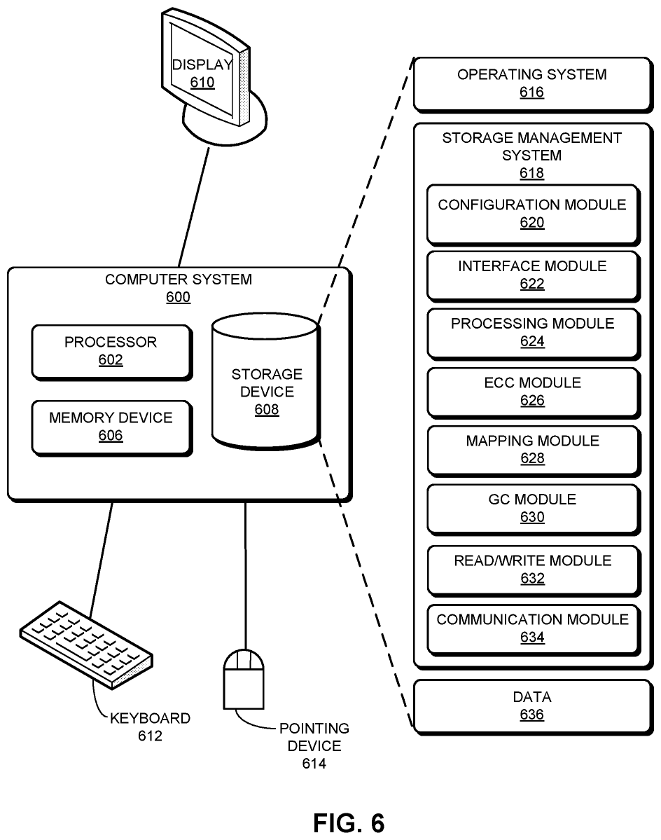

FIG. 6 illustrates an exemplary computer system that facilitates a high-density storage node with improved endurance and performance, in accordance with an embodiment of the present application. Computer system 600 includes a processor 602, a memory device 606, and a storage device 608. Memory device 606 can include a volatile memory (e.g., a dual in-line memory module (DIMM)). Furthermore, computer system 600 can be coupled to a display device 610, a keyboard 612, and a pointing device 614. Storage device 608 can be comprised of high-level storage cells (QLCs). Storage device 608 can store an operating system 616, a storage management system 618, and data 636. Storage management system 618 can facilitate the operations of one or more of: storage device 148 and controller 140. Storage management system 618 can include circuitry to facilitate these operations.

Storage management system 618 can also include instructions, which when executed by computer system 600 can cause computer system 600 to perform methods and/or processes described in this disclosure. Specifically, storage management system 618 can include instructions for configuring a region of storage device 608 as a low-level cell region and the rest as a high-level cell region (e.g., an SCL region and a QLC region, respectively) (configuration module 620). Storage management system 618 can also include instructions for facilitating respective namespaces for the SLC and QLC regions (configuration module 620). Furthermore, storage management system 618 includes instructions for receiving write instructions for host data from computer system 600 and restricting the write instructions within the SCL region (interface module 622). Storage management system 618 can also include instructions for reading data from both SLC and QLC regions (interface module 622).

Moreover, storage management system 618 includes instructions for performing CRC check, encryption/decryption, and compression/decompression during writing/reading operations, respectively (processing module 624). Storage management system 618 further includes instructions for performing ECC encoding/decoding with a medium strength for the SLC region and ECC encoding/decoding with a high strength for the QLC region (ECC module 626). Storage management system 618 can also include instructions for mapping a virtual address to a corresponding physical address (mapping module 628). In addition, storage management system 618 includes instructions for performing garbage collection on the SLC region to transfer data from the SLC region to the QLC region (GC module 630). Storage management system 618 includes instructions for accumulating data in a buffer to facilitate block-by-block data transfer to the QLC region (GC module 630).

Storage management system 618 can also include instructions for writing host data to the SLC region by appending the host data to the current write pointer, transferring data to the QLC region by performing sequential block-by-block write operations, and reading data from both SLC and QLC regions (read/write module 632). Storage management system 618 may further include instructions for sending and receiving messages (communication module 634). Data 636 can include any data that can facilitate the operations of storage management system 618, such as host data in the SLC region, transferred data in the QLC region, and accumulated data in the buffer.

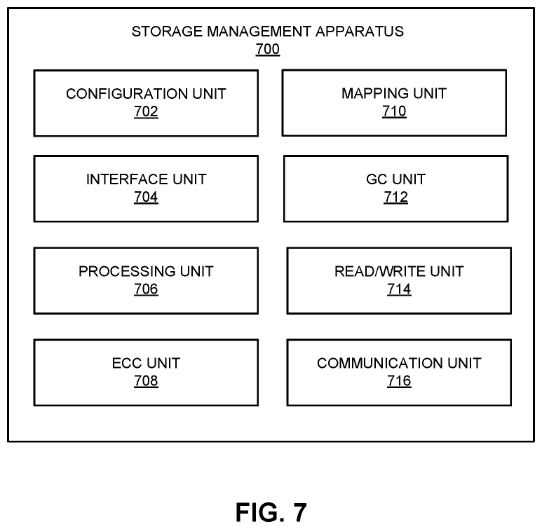

FIG. 7 illustrates an exemplary apparatus that facilitates a high-density storage node with improved endurance and performance, in accordance with an embodiment of the present application. Storage management apparatus 700 can comprise a plurality of units or apparatuses which may communicate with one another via a wired, wireless, quantum light, or electrical communication channel. Apparatus 700 may be realized using one or more integrated circuits, and may include fewer or more units or apparatuses than those shown in FIG. 7. Further, apparatus 700 may be integrated in a computer system, or realized as a separate device that is capable of communicating with other computer systems and/or devices. Specifically, apparatus 700 can include units 702-716, which perform functions or operations similar to modules 620-634 of computer system 600 of FIG. 6, including: a configuration unit 702; an interface unit 704; a processing unit 706; an ECC unit 708; a mapping unit 710; a GC unit 712; a read/write unit 714; and a communication unit 716.

The data structures and code described in this detailed description are typically stored on a computer-readable storage medium, which may be any device or medium that can store code and/or data for use by a computer system. The computer-readable storage medium includes, but is not limited to, volatile memory, non-volatile memory, magnetic and optical storage devices such as disks, magnetic tape, CDs (compact discs), DVDs (digital versatile discs or digital video discs), or other media capable of storing computer-readable media now known or later developed.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium.

Furthermore, the methods and processes described above can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules perform the methods and processes included within the hardware modules.

The foregoing embodiments described herein have been presented for purposes of illustration and description only. They are not intended to be exhaustive or to limit the embodiments described herein to the forms disclosed. Accordingly, many modifications and variations will be apparent to practitioners skilled in the art. Additionally, the above disclosure is not intended to limit the embodiments described herein. The scope of the embodiments described herein is defined by the appended claims.

What is claimed is:

1. An apparatus, comprising:
storage circuitry comprising a plurality of non-volatile memory cells, wherein a respective memory cell is configured to store a plurality of data bits;
an organization module configured to:
form a first region in the storage circuitry comprising a subset of the plurality of non-volatile memory cells, wherein a respective cell of the first region is reconfigured to store fewer data bits than the plurality of data bits; and
form a second region comprising a remainder of the plurality of non-volatile memory cells;
a programming module configured to write host data received via a host interface in the first region, wherein write operations received from the host interface are restricted to the first region; and
a transfer module configured to transfer valid data from the first region to the second region.

2. The apparatus of claim 1, wherein the transfer module is further configured to initiate the transfer in response to one of:
determining that a number of available blocks in the first region is below a threshold; and
determining a proactive recycling.

3. The apparatus of claim 1, wherein the transfer module is configured to:
rank a respective block in the first region to indicate a likelihood of transfer;
select one or more blocks with a highest ranking; and
determine data in valid pages of the one or more blocks as the valid data.

4. The apparatus of claim 1, wherein the transfer module is configured to:
transfer the valid data to a buffer in a controller of the apparatus;
determine whether a size of the data in the buffer has reached a size of a block of the second region; and
in response to the size of the data in the buffer reaching the size of the block of the second region, write the data in the buffer to a next available data block in the second region.

5. The apparatus of claim 1, wherein the first and second regions are configured to be accessible based on a first and a second non-volatile memory namespaces, respectively.

6. The apparatus of claim 1, further comprising an error-correction code (ECC) module configured to:
apply a first ECC encoding to the host data for writing in the first region; and
apply a second ECC encoding to the valid data for transferring to the second region, wherein the second ECC encoding is stronger than the first ECC encoding.

7. The apparatus of claim 6, wherein the ECC module is further configured to:
apply a first ECC decoding corresponding to the first ECC encoding for transferring the valid data to the second region; and
apply a second ECC decoding corresponding to the second ECC encoding for reading data from the second region.

8. The apparatus of claim 1, wherein the programming module is configured to write the host data in the first region by:
determining a location indicated by a write pointer of the first region, wherein the location indicates where data is to be appended in the first region; and
programming the host data at the location of the first region.

9. The apparatus of claim 8, further comprising a mapping module configured to:
in response to the host data being new data, generate a mapping between a virtual address of the host data to a physical address of the location of the first region; and
in response to the host data being an update to existing data, update an existing mapping of the virtual address of the host data with the physical address of the location of the first region.

10. The apparatus of claim 1, wherein a respective cell of the first region is a single-level cell (SLC) and a respective cell of the second region is a quad-level cell (QLC).

11. A storage device, comprising:
a plurality of non-volatile memory cells, wherein a respective memory cell is configured to store a plurality of data bits; and
a controller module configured to:
configure a subset of the plurality of non-volatile memory cells to form a first region in the storage device, wherein a respective cell of the first region is reconfigured to store fewer data bits than the plurality of data bits;
configure a remainder of the plurality of non-volatile memory cells to form a second region;
write host data received via a host interface in the first region, wherein write operations received from the host interface are restricted to the first region; and
transfer valid data from the first region to the second region.

12. The storage device of claim 11, wherein the controller module is further configured to initiate the transfer in response to one of:
determining that a number of available blocks in the first region is below a threshold; and
determining a proactive recycling.

13. The storage device of claim 11, wherein the controller module is further configured to:
rank a respective block in the first region to indicate a likelihood of transfer;
select one or more blocks with a highest ranking; and
determine data in valid pages of the one or more blocks as the valid data.

14. The storage device of claim 11, wherein the controller module is further configured to:
transfer the valid data to a buffer of the controller module;
determine whether a size of the data in the buffer has reached a size of a block of the second region; and
in response to the size of the data in the buffer reaching the size of the block of the second region, write the data in the buffer to a next available data block in the second region.

15. The storage device of claim 11, wherein the first and second regions are configured to be accessible based on a first and a second non-volatile memory namespaces, respectively.

16. The storage device of claim 11, wherein the controller module is further configured to:
apply a first error-correction code (ECC) encoding to the host data for writing in the first region; and
apply a second ECC encoding to the valid data for transferring to the second region, wherein the second ECC encoding is stronger than the first ECC encoding.

17. The storage device of claim 16, wherein the controller module is further configured to:
apply a first ECC decoding corresponding to the first ECC encoding for transferring the valid data to the second region; and
apply a second ECC decoding corresponding to the second ECC encoding for reading data from the second region.

18. The storage device of claim 11, wherein the controller module is further configured to write the host data in the first region by:
determining a location indicated by a write pointer of the first region, wherein the location indicates where data is to be appended in the first region; and
programming the host data at the location of the first region.

19. The storage device of claim 18, wherein the controller module is further configured to:
in response to the host data being new data, generate a mapping between a virtual address of the host data to a physical address of the location of the first region; and
in response to the host data being an update to existing data, update an existing mapping of the virtual address of the host data with the physical address of the location of the first region.

20. The storage device of claim 11, wherein a respective cell of the first region is a single-level cell (SLC) and a respective cell of the second region is a quad-level cell (QLC).
